(19) United States
(12) Patent Application Publication
(10) Pub. No.: US 2022/0365248 A1
(43) Pub. Date: Nov. 17, 2022

(54) FABRICATION OF NANO-PATTERNED SURFACES FOR APPLICATION IN OPTICAL AND RELATED DEVICES

(71) Applicant: UNIVERSITY COLLEGE CORK - NATIONAL UNIVERSITY OF IRELAND, CORK, Cork City (IE)

(72) Inventors: Parvaneh Mokarian-Tabari, Cork (IE); Michael Morris, Co. Cork (IE); Ramsankar Senthamaraikannan, Cork (IE)

(73) Assignee: UNIVERSITY COLLEGE CORK - NATIONAL UNIVERSITY OF IRELAND, CORK, Cork City (IE)

(21) Appl. No.: 17/573,994

(22) Filed: Jan. 12, 2022

Related U.S. Application Data
(63) Continuation of application No. 16/070,445, filed on Jul. 16, 2018, now abandoned.

(30) Foreign Application Priority Data
Jan. 14, 2016 (GB) 1600745.2

(51) Int. Cl. G02B 1/113; H01L 31/0216; H01L 33/20

(52) U.S. Cl. CPC G02B 1/113; H01L 31/02161; H01L 31/02168; H01L 33/20; B82Y 20/00

(57) ABSTRACT

The invention provides a solution based process based on high molecular weight block copolymer (BCP) nanolithography for fabrication of periodic structures on large areas of optical surfaces. In one embodiment there is provided method of fabricating a nano-patterned surface for application in a photonic, optical or other related device, said method comprising the steps of: providing a substrate material; depositing a block copolymer (BCP) material on the substrate material; and phase separating the BCPs using at least one solvent selected to facilitate polymer chain mobilisation and lead to phase separation to fabricate said nano-patterned surface; wherein the nano-patterned surface comprises an ordered array of structures and having a domain or diameter of 100 nm or greater. A new photonic device and optical device is also described.

### CROSS REFERENCE TO RELATED APPLICATIONS

This application is a continuation under 35 U.S.C. § 120 of copending U.S. application Ser. No. 16/070,445 filed on Jul. 16, 2018, now abandoned, which is a 371 National Phase Entry of International Patent Application No. PCT/EP2017/050736 filed on Jan. 13, 2017, which claims benefit of foreign priority under 35 U.S.C. § 119(d) of Great Britain Patent Application No. 1600745.2, filed Jan. 14, 2016, the contents of each of which are incorporated herein by reference in their entireties.

### FIELD

The invention relates to the fabrication of nano-patterned surfaces for application in optical and related device.

### BACKGROUND

Electromagnetic radiation, here meaning UV light, visible light, near infrared light, mid infrared light and far infrared light, is reflected at the interface between two media due to abrupt changes in the speed of light as it passes from one media into the next. Here ‘abrupt’ means over a distance approximating the wavelength of light in the media. Since the speed of light is defined by the refractive index of the material in which it is travelling, optical reflections can equivalently be described as arising from abrupt changes in the refractive index of the media.

Undesirable optical reflections can be mitigated by gradating the refractive index experienced by light as it travels from one media into the next. Practically this can be achieved by sub-wavelength texturing or patterning the substrate media. Texturing reduces the abruptness of the refractive index discontinuity experienced by light and thereby the optical reflectivity.

The extensive benefits of the new generation of nanostructured surfaces is very promising for enhancing light absorption efficiency in optical or photonic devices. However, the low throughput and the high cost of available technologies such as interference lithography for fabrication of nanostructures has proved to be a difficult technological hurdle for advanced manufacturing.

It is known to use block copolymer (BCP) nanolithography for fabrication of periodic structures on large areas of optical surfaces, such as a Led Emitting Device surface. The total efficiency of LEDs is determined by the product of the internal quantum efficiency and the extraction efficiency. The internal quantum efficiency has been improved more than 80%, but the extraction efficiency is less than 10%. This is due to the large difference of the refractive index between substrates and the air which leads to total internal reflection.

Nano patterning the surface of LEDs using block copolymers can improve the extraction efficiency. Nano-structures have been widely studied as photonic crystals, an antireflection structure, and nano-textures for higher luminescent LEDs. However, these structures are generally fabricated by electron beam lithography (EBL) and dry etching. There are two major problems with electron beam lithography method:
(1) The EBL process is very slow and also expensive which makes it impractical for industrial scale production.
(2) There is a low etch contrast (etch contrast is the difference in etch rate between the resist used to create the structures and substrate being etched) between polymer resists and substrates such as GaN, InGaAlP, Sic and sapphire. It is, therefore extremely difficult (if not impossible) to pattern transfer the lithography masks to the substrate and fabricate tall arrays of nanopillars [Samsung 2009].

Block copolymer (BCP) self-assembly is a solution-based process that offers an alternative route to produce highly ordered nanostructures. There has been a wealth of scientific research as well as technological and commercial motivation for using BCPs in the photonics industry. Numerous publications in the art exist, including ‘Nanofabrication of III-V semiconductors employing diblock copolymer lithography’ Thomas F Kuech and Luke J Mawst Published 21 Apr. 2010•2010 IOP Publishing Ltd, Journal Of Physics D: Applied Physics, Volume 43, Number 18; Fabrication of a sub-10 nm silicon nanowire based ethanol sensor using block copolymer lithography Sozaraj Rasappa, Dipu Borah, Colm C Faulkner, Tarek Lutz, Matthew T Shaw, Justin D Holmes and Michael A Morris; Published 22 January 2013; European Patent Publication number EP2599109 (Aissou); PCT patent publication numbers WO2009/079241 (Wisconsin) and WO2013/143813 (Asml Netherlands).

However, the main problem with BCP state of the art techniques is advancing the technology beyond 1D and 2D photonic crystals in the range of visible light which is slow and difficult. The reason for this lies in the fact that for nanofeatures to modulate visible photons with wavelengths in the range 400-700 nm, they must be greater than 100 nm (typically ¼ wavelength). BCPs do not easily phase separate into their signature ordered pattern above 100 nm. This is due to the significant kinetic penalty arising from higher entanglement in high molecular weight polymers. Moreover for applications that require anti-reflective properties the state-of-the-art (SOA) antireflective properties of sub-wavelength structures derived from BCPs has an average reflectivity of about 1% at best and often above 1%. It is desirable to have a much lower reflectivity value.

It is an object to provide a new and improved fabrication of nano-patterned surfaces for application in optical, photonic and related device applications.

### SUMMARY

According to the invention there is provided, as set out in the appended claims, a method of fabricating a nano-patterned surface for application in a photonic, optical or other related device, said method comprising the steps of:
providing a substrate material;
depositing a block copolymer (BCP) material on the substrate material; and
phase separating the BCPs using at least one solvent selected to facilitate polymer chain mobilisation and lead to phase separation to fabricate said nano-patterned surface; wherein the nano-patterned surface comprises an ordered array of structures and having a domain or diameter of 100 nm or greater.

In one embodiment the phase separation step uses two or more solvents and the solvent ratio is selected to facilitate the chain mobilisation and lead to phase separation.

In one embodiment the structure domain or diameter size is tuned by selecting the volume fraction of the block components.

In one embodiment the method takes place in a sealed housing defining a volume and the solvent is selected based on said volume.

The invention achieves phase separation in high molecular weight BCPs, forming well-ordered hexagonal cylinder patterns with feature size and periodicity of ˜115 and 180 nm respectively. Pattern transfer of such large features can be made for the first time. By extending (BCP) nano-patterning beyond the-state-of-the-art, sub-wavelength structures on Si, glass, GaN, and germanium for enhanced broadband antireflection (AR) in photonic devices operating in the wavelength range from visible to near infrared (Vis-NIR) can be fabricated. A reduction in reflectivity by a factor of >100 achieved by overcoming the 100 nm size limit in block copolymers. A broadband antireflection less than 0.16% was observed, over the entire spectrum of 400-900 nm at angle of incidence (AOI) of 30°.

In one embodiment the high molecular weight BCP comprises 440k-353k) g/mol, volume fraction of PS:P2VP 58:42.

In one embodiment the step of depositing the block copolymer (BCP) material on the substrate material is performed by at least one of spin coating film; drop casting or dip coating.

In one embodiment there is provided the step of texturing the height of the nano-patterned surface to a desired value.

In one embodiment the nano-pattern surface comprises an array of pillar or wire like structures and having a domain or diameter of approximately 100 nm or greater.

In one embodiment the nano-pattern surface comprises an array of substantially conical shaped structures and having a diameter of approximately 100 nm or greater and a length of approximately 100 nm or greater.

In one embodiment the thickness of the BCP material is selected from a range of 100 nm to 500 nm.

In one embodiment the substrate layer comprises at least one of: semiconductor material, silicon; gallium nitride; silicon carbide; glass; metal or plastic.

In one embodiment the step of controlling the size and shape of the nano-pattern surface.

In one embodiment the step of incorporating metal oxide particles within the BCP material.

In one embodiment there is provided the step of direct etching through a metallised mask.

In one embodiment there is provided the step of transferring the nano-pattern to the substrate material to provide an antireflective surface with a low reflectivity in a wide range of wavelength.

In one embodiment there is provided a subwavelength grating made from the same material as the substrate and the index matching at the substrate interfaces provides improved anti-reflecting performance.

In another embodiment there is provided a photonic or optical device comprising a substrate material wherein a surface of the substrate material comprises an array of pillar or wire like structures and having a domain or diameter of approximately 100 nm or greater.

In one embodiment the substrate material and the array of pillar or wire like structures are the one material with no interface layer or boundary between the array and the substrate.

In a further embodiment there is provided a method of fabricating a nano-patterned surface for application in a photonic, optical or other related device, said method comprising the steps of:
providing a substrate material;
depositing a high molecular weight block copolymer (BCP) material on the substrate material; and
phase separating the high molecular weight BCPs without modifying the substrate material or the BCP material to fabricate said nano-patterned surface.

In another embodiment there is provided a system for fabricating a nano-patterned surface for application in a photonic, optical or other related device, said system comprising one or more modules adapted for:
providing a substrate material;
depositing a high molecular weight block copolymer (BCP) material on the substrate material; and
phase separating the high molecular weight BCPs without modifying the substrate material or the BCP material to fabricate said nano-patterned surface.

In one embodiment the invention provides fabrication of nano-patterned surfaces of >100 nm feature size via block copolymer lithography for application in photonic and related device applications.

This can be achieved by engineering sub-wavelength structures on the surface of LED substrates using block copolymers. The ordered sub-wavelength patterns will reduce reflections at the LED-air interface and thereby increase light output of the emitters. The highly ordered pattern will improve and control the direction of the emitted light.

It will be appreciated that the invention greatly improves anti-reflection properties without using any coatings. The coating approach has numerous disadvantages but the primary ones here are: (1) they are invariably narrowband, and (2) they are vulnerable to damage at high optical powers. By comparison, the invention is both broadband and will survive much higher optical power densities due to the absence of a coating (typically a dielectric material).

In one embodiment there is provided a method for phase separation of high molecular weight block copolymer for fabrication of large domains (>100 nm) for photonic and related device applications.

In one embodiment the invention comprises the step direct etching through a metallised mask.

In one embodiment there is provided the step of incorporating metal oxide particles within the polymer.

Light emitting materials such as gallium nitride and silicon carbide can be used as the substrate.

In one embodiment the size and shape of the nanostructure can be customised by the molecular weight and volume fraction of the polymer blocks.

In one embodiment pattern transferred the BCP mask to silicon substrate by reactive ion etch (ICP-RIE). The final product is black silicon, consists of hexagonally packed conic Si nano-features with diameter above 100 nm and periodicity of 200 nm. The height of the Si nanopillars varies from 100 nm to higher than 1 micron.

It will be appreciated that the subwavelength grating is made from the same material as the substrate (Si), the index matching at the substrate interfaces has led to much improved anti-reflecting performance. The reflectivity of the silicon substrate shows one order of magnitude reduction in a broad range of wavelength from NIR to UV-visible, below 1%.

It will be appreciated that the substrate material can be glass or sapphire. Glass and sapphire can be used for application in electronic device displays. The BCP process can be modified to achieve phase separation. The dimension of the features has to be modified to accommodate the higher refractive index of glass for modulation of light.

The etch process can be implemented on glass and sapphire. Amorphous glass is a hard material and it is not easy to (plasma) etch. Most glass etch recipes are based on wet etch. However, for the application, we need to apply anisotropic etch to fabricate nanopillars.

In another embodiment, high-resolution, cost-effective patterning of curved surfaces is essential for many applications, such as microelectromechanical systems (MEMS), electronic devices, and optics. Although soft nanoimprint lithography has been demonstrated as a high-throughput, low-cost lithographic technique, it still needs a soft mould (usually PDMS based) which will not stand the harsh etch environment to create tall glass nanopillars. Nanoimprint lithography usually cannot provide high aspect ratio (e.g. >2) nanopillars. The large BCP patterning technique according to the invention can be applied on curved surfaces without any need for the mould.

### BRIEF DESCRIPTION OF THE DRAWINGS

The invention will be more clearly understood from the following description of an embodiment thereof, given by way of example only, with reference to the accompanying drawings, in which:

FIG. 1 illustrates a large block copolymer PS-b-P2VP phase separated to hexagonally ordered pattern structure (a) AFM topography image, (b) Fast Fourier Transform showing a very high level of order.

FIG. 2 illustrates a quantitative analysis of the feature size in FIG. 1; The table provides the information regarding to the dimension of the areas analysed including defects and number of features in (a).

FIG. 3 illustrates domain size distribution for diameter (CD). Data was collected from 17 images of 10 individual samples. An example of the output detected features and Delaunay triangulation are also shown.

FIG. 4 illustrates the pitch size distribution is 180±18 nm for 80% of the spacing in FIG. 1.

FIG. 5 illustrates SEM images of Si nanopillars fabricated by large molecular weight block copolymers. FIGS. 5(a) to 5(c), Top down images with different etch times. FIGS. 5(d)-5(f), the cross section image of the pillars with different height. FIG. 5(d) shows 100 nm, FIG. 5(e) shows 485 nm, and FIG. 5(f) shows 600 nm.

FIG. 6 illustrates optical characterisations of nanostructured Si samples. Broadband omnidirectional antireflection properties of silicon nanopillars by block copolymer self-assembly 30-75°. (a) reflectivity of planar Si (triangles) and 870 nm SiNPs for different values of AOI: 30° (circle), 45° (star), 60° (diamond), 70° (triangle), 75° (square), (b) the SEM cross section image of SiNPs with a height of 870 nm, base diameter of 130 nm and apex diameter of 70 nm. Note the Y-Axis is logarithmic (c) Highly reflective planar Si and (d) photographs of nano-patterned Si that appears uniformly black by elimination of visible light reflection compared to Si (100) substrate.

FIG. 7 illustrates angular dependence of SiNPs with various height at different angle of incidence: (g) 45°, (h) 60°, (i) 70° and (j) 75°. Note that the y-axis is logarithmic scale for the nano-patterned Si data (up to the break point) and linear scale for planar Si. The legend in (g-j) demonstrate average SiNP's height.

FIG. 8 illustrates a schematic of steps involved in nano-patterning with BCPs, according to one embodiment.

FIG. 9 shows the AFM topography image of PS-b-P2VP films solvo/thermal annealing at 70° C., exposed to methanol, THF, toluene, toluene and methanol combined and THF and chloroform combined.

FIG. 10 shows the annealing time variation from 2 to 24 hours after exposure to THF:CHCl₃ with volume fraction of (2:1) at room temperature.

FIG. 11 illustrates PS-b-P2VP with different film thicknesses on Si substrate after exposure to THF and ChCl3 at room temperature for 60 minutes. All images are 2×2 micron.

FIG. 12(a) AFM topography image of PS-b-P2VP on GaN after phase separation and (b) top-down SEM image of GaN dots after pattern transfer.

FIG. 13 illustrates AFM topography image of the PS-b-P2VP films (a-d) after exposure to ethanol at 40° C. for 45 minutes and (e-h) after immersing the samples in ethanol at 40° C. for 45 minutes.

FIG. 14 illustrates the effect of critical film thickness and swelling ratio. The best ordered patterns are marked by purple frame or border. The films are exposed to THF:ChCl3 with different ratio.

FIG. 15 Iron oxide dots on (a) Si substrate and (b) GaN (LED) substrate after UV/Ozone.

FIG. 16 illustrates cross section SEM images of highly tuneable Si nanopillars made by large BCPs with relevant heights at (a) 180 nm, (b) 310 nm, (c) 515 nm, (d) 610 nm, (e) 870 nm and (f) 1150 nm. The scale bars are 200 nm.

FIG. 17 illustrates SEM cross-section images of germanium nanopillars after 5-30 minutes etch with relevant height of the nanopillars at (a) 370 nm, (b) 705 nm, (c) 800 nm, (d) 1080 nm, (e) 1325 nm and (f) 1370 nm.

FIG. 18 illustrates (a) AFM image of Ps-b-P2VP on glass, (b) Top-down SEM image of glass nanodots after pattern transfer of the metalised mask in (a), (c) SEM cross section image glass of nanopillars with metal oxide on top.

### DETAILED DESCRIPTION OF THE DRAWINGS

The invention provides a solution based process based on high molecular weight block copolymer (BCP) nanolithography for fabrication of periodic structures on large areas of optical surfaces.

Block copolymer self-assembly technique is a solution based process that offers an alternative route to produce highly ordered photonic crystal structures. BCPs forms nanodomains (5-10 nm) due to microphase separation of incompatible constitute blocks. The size and shape of the nanostructure can be customised by the molecular weight and volume fraction of the polymer blocks. However, the major challenge is BCPs do not phase separate into their signature ordered pattern above 100 nm, whereas for nano-features to be used as photonic gratings, they must be greater than 100 nm (typically ¼ wavelength). This is due to significant kinetic penalty arising from higher entanglement in high molecular weight polymers.

The invention produces block copolymers to phase separate into periodic domains greater than 100 nm. The process does not include any blending with homopolymers, or adding colloidal particles, disclosed in the prior art.

In one embodiment a BCP mask is pattern transferred to silicon substrate by reactive ion etch (ICP-RIE). The final product can be black silicon, and consists of hexagonally packed conic Si nano-features with diameter above 100 nm and periodicity of 200 nm. The height of the Si nanopillars varies from 100 nm to 1 micron.

Characterization of the angle dependent optical reflectance properties of the black silicon was performed. The antireflective properties of the Si nanostructures were probed in the 400 nm-2500 nm wavelength range and compared to an Au reflectance standard. As the subwavelength grating is made from the same material as the substrate (Si), the index matching at the substrate interfaces has led to highly improved anti-reflecting performance. The reflectivity of the silicon substrate shows one order of magnitude reduction in a broad range of wavelength from NIR to UV-visible, below 1%. The simplicity of the solution based large block copolymer nanolithography and the capability of integration to existing fabrication process, makes the technique of the invention a very attractive alternative for manufacturing photonic crystals on large, arbitrary shaped and curved objects such as photovoltaics and IR camera lenses for medical imaging or LED devices.

The invention provides a practical and effective way of fabricating high aspect ratio sub-wavelength structures (>100 nm to interact with light) on semiconducting substrates by using high molecular weight block copolymers (BCPs). The invention provides a method or process for:
(a) achieving phase separation in high molecular weight BCPs without any modification of the substrate or the polymer;
(b) It provides an effective and easy method for texturing semiconducting materials. The nanostructures alter the interaction of light with semiconductors and lead the light to transfer easily to a barrier/junction needed for photonic devices such as LEDs, Photovoltaics, imaging and communication technology, antireflective coatings and fabrication of black silicon;
(c) It provides a platform for mass production of subwavelength nanostructures on semiconducting materials for photonic devices and sensors in a wide wavelength range from UV-VIS to Near IR; and
(d) At the same time, the samples yield structural superhydrophobicity for self-cleaning and structural colouring with no coating layer or pigmentation (antireflective coating), suitable for harsh environmental condition with high robustness and stability.

Block copolymers do not phase separate above approximately 100 nm feature size due to high energy barrier involved with mobilising the highly entangles chain. The invention induces phase separation in hexagonally packed cylindrical forming BCPs with very high molecular weight (˜800,000 g/mol) with no blending and no mixing with homopolymers. The photonic structure is kinetically trapped under extreme confinement regime and by finding the critical thickness range and swelling rate of the film during annealing. The pattern is successfully transferred to a semiconducting substrate. The result is an antireflective coating/black Si with minimum reflectivity in a wide range of wavelength.

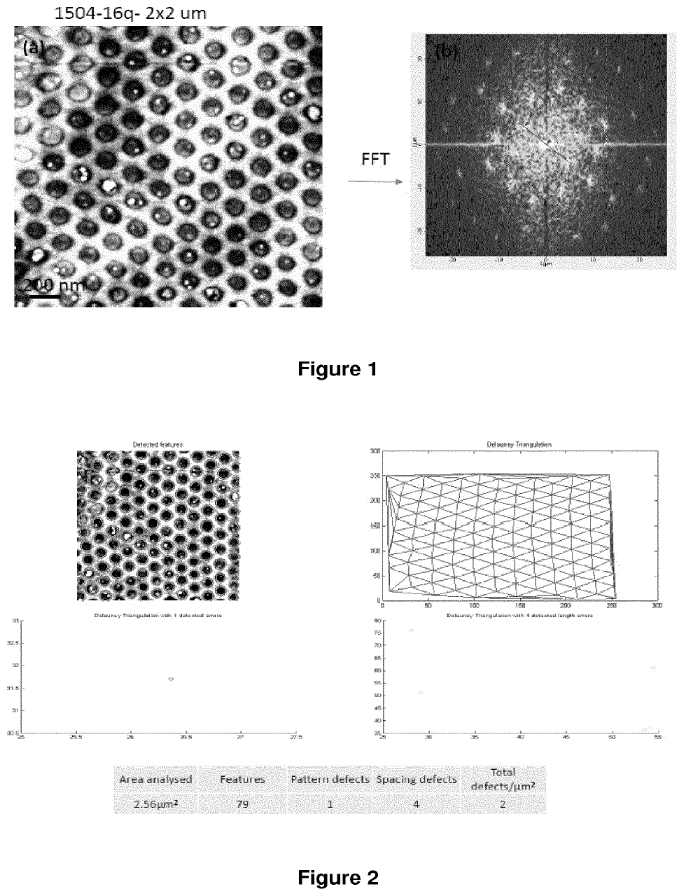

FIG. 1 illustrates large block copolymer PS-b-P2VP phase separated to hexagonally ordered pattern structure. (a) AFM topography image, (b) Fast Fourier Transform showing a very high level of order. The table provide the information regarding to the dimension of the features in (a).

| | Cylinder diameter | | |
|---|---|---|---|
| Sample ID | (nm) | Pitch(nm) | Film thickness |
| 1504-16q (thin film) | 115 ± 19 | 180 ± 18 | 163 + 2.71 nm |

Note:
dimensions reported here represent 80% of the features.

FIG. 2 illustrates quantitative analysis of the feature size in FIG. 1

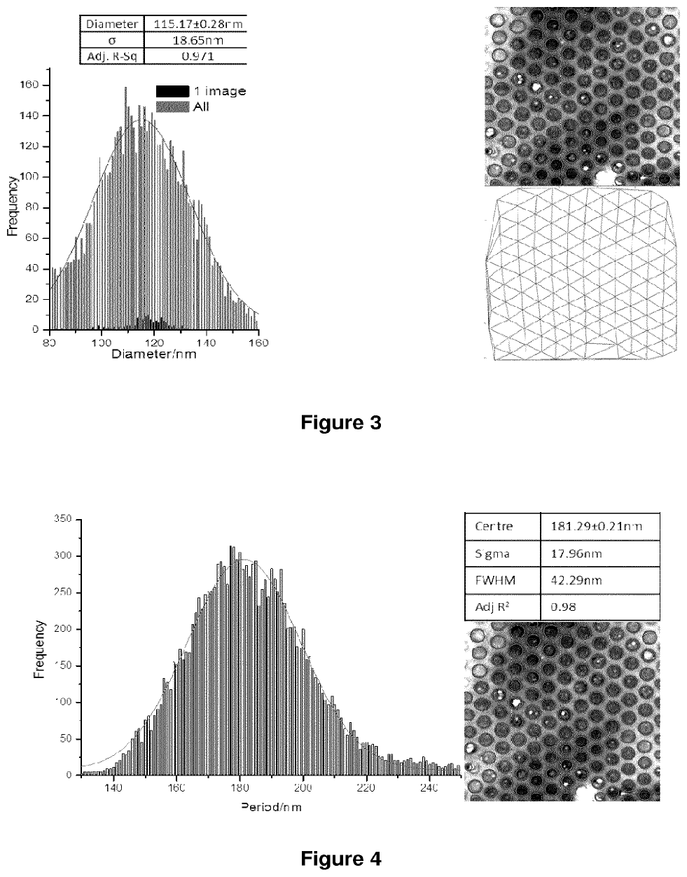

FIG. 3 illustrates domain Size distribution of the sample in FIG. 1. 80% of the domains have feature size of 115±19 nm.

FIG. 4 illustrates the pitch size distribution is 160-200 nm for 80% of the spacing in FIG. 1

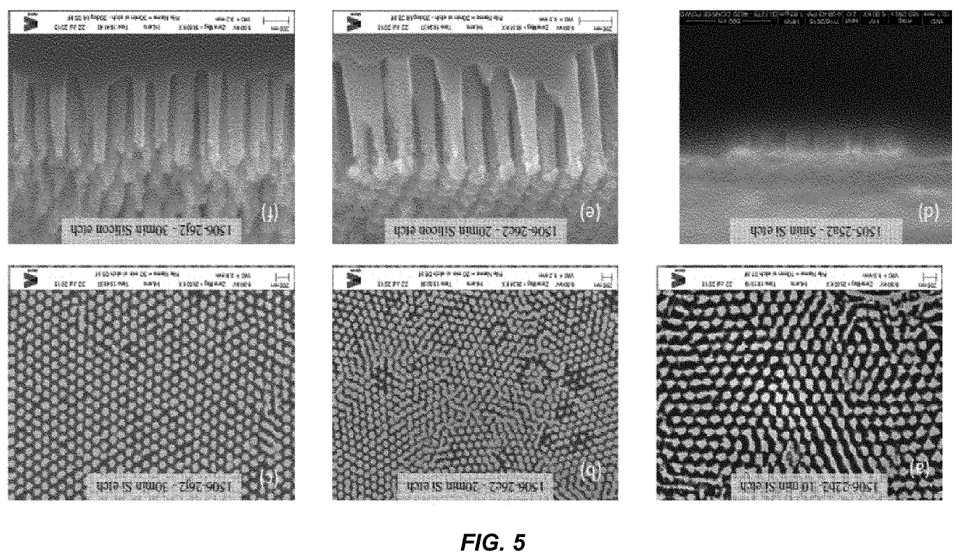

FIG. 5 illustrates SEM images of Si nanopillars fabricated by large molecular weight block copolymers. Top row, top down images with different etch time. Bottom row, the cross section image of the pillars with different height (d) 100 nm, (e) 485 nm and (f) 600 nm.

To minimise the reflection from Si and make anti reflective coating, surface texturing is employed. Roughening of the surface reduces reflection by increasing the chances of reflected light bouncing back onto the surface, rather than out to the surrounding air. In the present inventive process method, a well ordered packed arrays of Si nanopillars are etched to a semiconductor substrate with heights varied from 100 nm-1350 nm. It will be appreciated that in the context of the present invention, the process does not make use of a method to “roughen” the surface, which is a random and uncontrolled process. Instead BCPs are a way to pattern or texture the substrate which is a controlled process and a different process to roughening.

The reflectance of Si decreases dramatically (>90%) in comparison to flat Si by changing the height of the pillars. The reflectance reduces progressively by increasing the pillars height from 100 nm to 600 nm and above. The 870 nanopillars show the best antireflective property. An added advantage is that the textured surface has the super-hydrophobic property in a way that repels water on a flat surface.

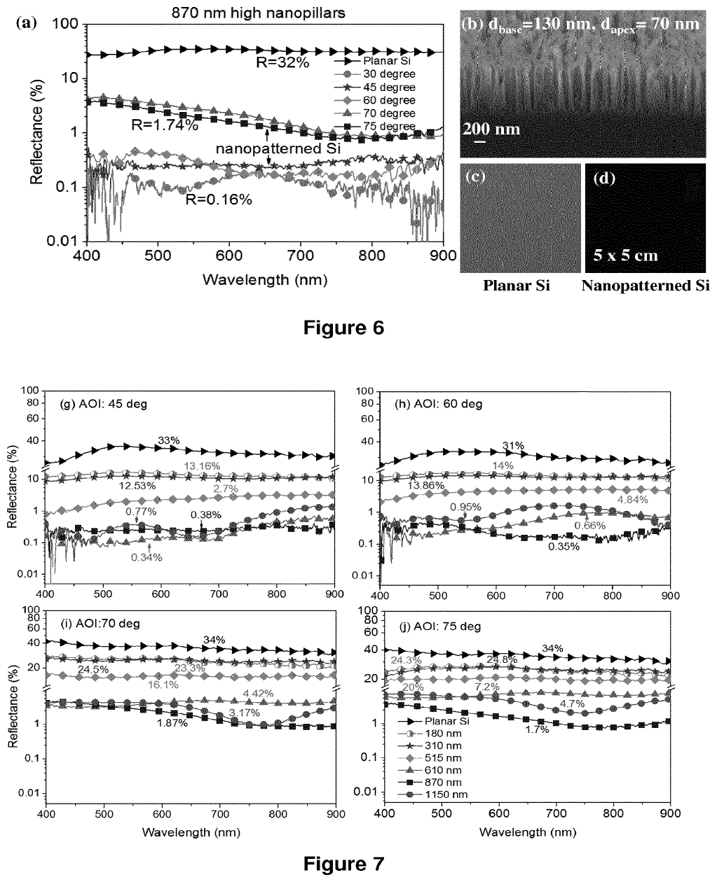

FIG. 6 illustrates optical characterisations of Si samples. Broadband omnidirectional antireflection properties of silicon nanopillars by block copolymer self-assembly 30-75° were obtained where (a) reflectivity of planar Si (black triangles) and 870 nm SiNPs for different values of AOI: 30° (circle), 45° (star), 60° (diamond), 70° (triangle), 75° (square), (b) the SEM cross section image of SiNPs with a height of 870 nm, base diameter of 130 nm and apex diameter of 70 nm. Note the Y-Axis is logarithmic (c) Highly reflective planar Si and (d) photographs of nano-patterned Si that appears uniformly black by elimination of visible light reflection compared to Si (100) substrate.

FIG. 7 illustrates. angular dependence of SiNPs with various height at different angle of incidence: (g) 45°, (h) 60°, (i) 70° and (j) 75°. Note that the y-axis is logarithmic scale for the nano-patterned Si data (up to the break point) and linear scale for planar Si. The legend in (g j) demonstrate average SiNP's height.

### LED Embodiment

The LED performance is improved by minimising the total internal reflection by nano-patterning the surface. Attempts have been made to prevent reflection by creating a refractive index gradient by providing nanometer level irregularities on the surface of light-emitting elements as well as extracting primary diffracted light by creating a diffraction grating on the surface.

However, these measures require extremely minute processing on the nanometer level. The use of electron beam lithography has been studied at the research level while nano imprinting has been examined for volume production. However, these methods have the shortcoming of requiring the use of costly equipment, while also encountering production difficulty due to the need to fabricate regular structures of nanometer size. In addition, technologies consisting of roughening a light-emitting surface by treating with hydrochloric acid, sulphuric acid, hydrogen peroxide or a mixture thereof, have an effect on crystallinity of the substrate and some surfaces cannot be roughened depending on the exposed orientation. Consequently, since a light-emitting surface cannot always be roughened, there are limitations on the improvement of light extraction efficiency. Another drawback of roughening technique is the need for an additional passivation process to prevent unidirectional etching. The major problem with this method is there is very little control on how the textured surface directs the light out of the LED, resulting in lambertian radiation pattern.

The approach of the present invention is more cost effective than other lithographic techniques and less harsh than chemical surface roughening currently used to enhance the overall efficiency of LEDs. In chemical roughening process, the uniformity and the depth of the grating cannot be controlled. On the contrary, with the BCP technique, it is possible to fabricate high aspect ratio and ordered nano-features which improves the directionality of the beam where a more collimated beam profile is needed. These combined results cannot be achieved by surface roughening, as the light is scattered in different directions.

In solar cells industry, the main problem is the cost and complexity of material processing. This include the expensive high temperature chemical vapour deposition of silicon nitride layer to make anti reflective coatings. The technology completely eliminates this step and therefore, it is a much simpler way of manufacturing black silicon for applications in highly efficient photovoltaics. The process is also environmentally friendly as it doesn't require the use of volatile and toxic silane or in fact any other harmful substances. This is a step towards green and clean energy resources.

### Sensor Embodiment

It will be appreciated that the black silicon, produced according to the invention, can be used to enhance the sensitivity of image sensors in near infrared (NIR) regions for example in night vision cameras (for defence industry), medical imaging devices used in radiology, dental and dermatology. In telecommunication industry it can be used for taking a sharper image on mobile phone cameras.

### Optical Elements Embodiment

Non-planar optical elements that can be treated according to the invention include optical lenses, metal microlens moulds, fiber optic lenses, etc. Planar optical elements that can be treated according to the invention include laser windows, optical polarisers, splitters and any other optical elements.

### Experimental Results

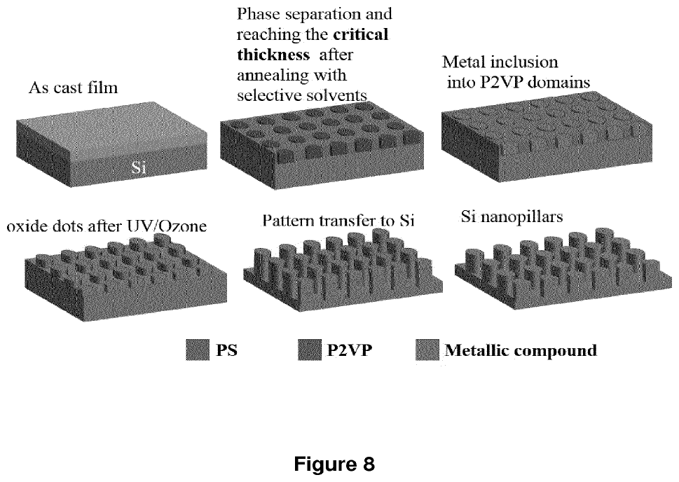

The process, and devices produced, of the invention boost the performance of light emitting diodes (LEDs) by nano-patterning the surface of LED substrate using block copolymers. FIG. 8 illustrates a process flow diagram for fabrication of sub-wavelength structures on the surface of LED substrates.

The substrate material can be Silicon and a block copolymer (BCP) material is deposited on the substrate material. The block copolymer can be used as a sacrificial layer, metal oxide inclusion as hard mask and dry etch technique can be used to nano-pattern the surface to improve the efficiency of LEDs. The block copolymer is made of two or more chemically incompatible constitutes. The volume fraction of the constitutes can vary for example from 20:80 to 80:20. A higher molecular weight block copolymer (BCP) can be used to obtain long-range microdomains on the LED substrates. Polystyrene-block-poly2vinylpyridine (PS-b-P2VP) (number-average molecular weight, Mn, PS=440 kg mol⁻1, Mn, PMMA=353 kg mol⁻1) and iron (III) nitrate nonahydrate were used to fabricate hard mask.

FIG. 8 illustrates step by step process flow diagram of the fabrication of sub-wavelength structures on the surface of LED substrates, according to an exemplary embodiment of the invention. In step (i) the polymer film is deposited from a solution comprised of one or two organic solvents. The solution can be used at room temperature or heated above a certain temperature. Here toluene:tetrahydrofuran with the ratio of 80:20 was used. The film can be deposited via spin coating, dip coating, spray or other methods of coating. In step (ii), the polymer film is exposed to one or two organic solvent with a ratio that facilitate the chain mobilisation and lead to phase separation, either at temperature range RT to 200° C. and higher. Here THF:CHCl₃ with volume ratio of 2:1 was used, for an hour at room temperature. Solvent annealing was carried out with two small vials containing 2 ml THF and 1 ml CHCl₃ placed inside a glass jar with a suitable volume, along with the BCP sample. In step (iii) Phase separated BCP thin film were reconstructed by exposing the film to ethanol vapour. A 0.8 wt. % of iron nitrate ethanolic solution was spin cast on silicon substrate. In Step (IV) UV/Ozone treatment was utilised to oxidize the precursor and remove the matrix polymer. In step (V) the pattern is transferred to the substrate via an etch process. For these specific samples, the silicon etch was performed using C₄F₈ (90 sccm) and SF₆ (30 sccm) gases for various duration of time with an inductively coupled plasma (ICP) and reactive ion etching (RIE) powers of 600 W and 15 W, respectively, at 2.0 Pa with a helium backside cooling pressure of 1.3 kPa to transfer the patterns into the underlying substrate. The GaN etch was performed using CH₄ (5 sccm), H₂ (15 sccm) and Ar (25 sccm) gases for desired time with ICP and RIE powers of 500W and 45W. In step (VI) the iron oxide is removed by immersing the samples in a diluted solution of oxalic acid bath.

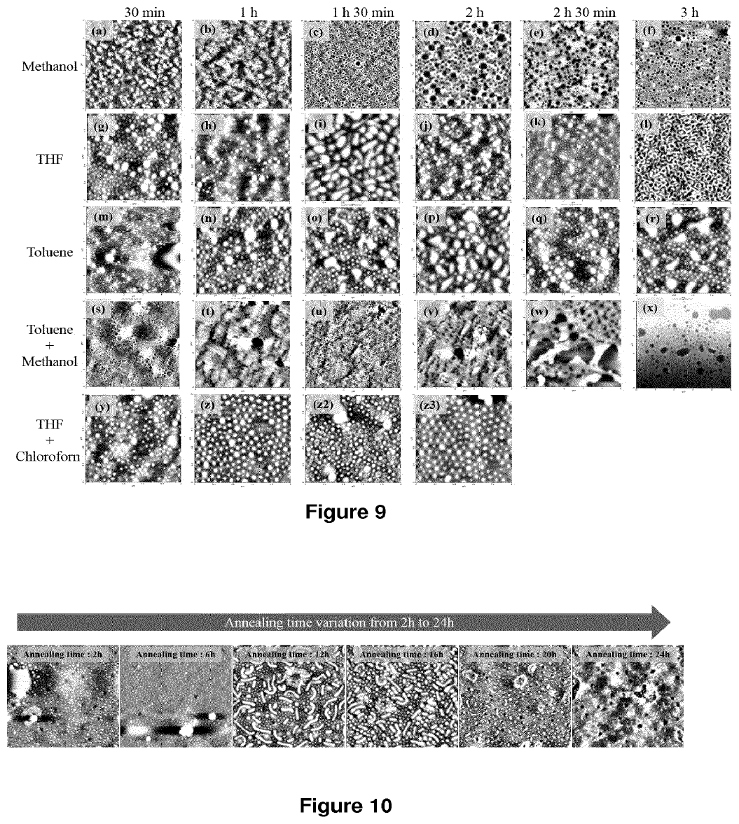

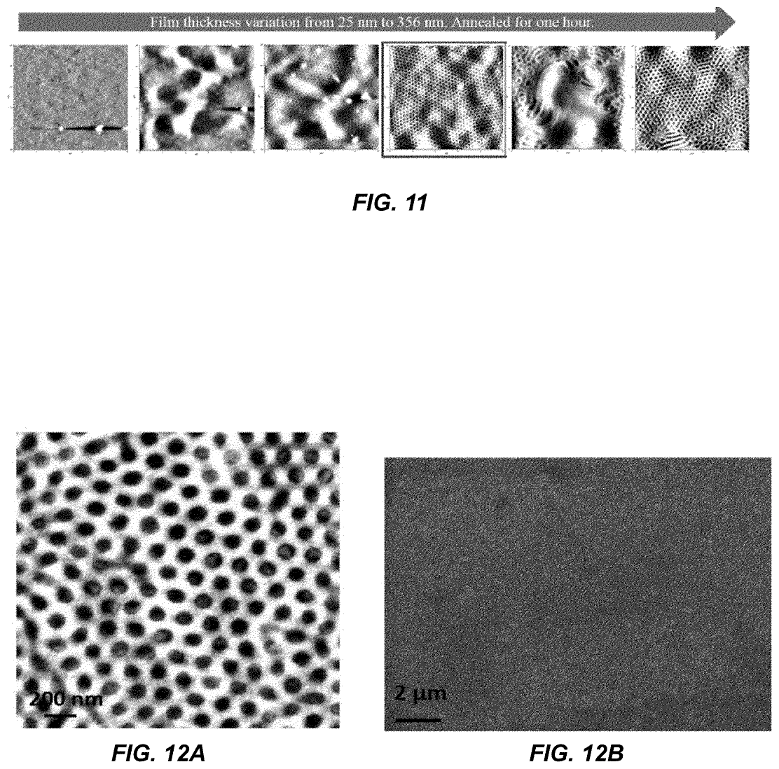

Solvent annealing of block copolymer films on silicon were performed. FIG. 9 shows the AFM topography image of PS-b-P2VP films solvo/thermal annealing at 70° C., exposed to methanol, THF, toluene, toluene and methanol combined and THF and chloroform combined. All images are 2×2 micron. From FIG. 9 it is clear that combination of THF and chloroform (FIG. 9 bottom row) at 70° C., induces the best phase separation with highest level or order among others. After 30 minutes the phase separation starts (FIG. 9 bottom row first panel on the left) and after 2 hours annealing a well ordered pattern is forms (FIG. 9 bottom row last panel on the right). Clearly the combination of tetrahydrofuran and chloroform provides the best morphology. In FIG. 10, the annealing time is varied from 2 hours to 24 hours, at room temperature. In FIG. 11 the critical thickness is examined. The film is annealed for 1 hour only at room temperature with (THF:ChCl₃). The film thickness varied between 25 to 356 nm in this example.

The PS-b-P2VP thin film was formed by spin coating the block copolymer solution (4500 rpm for 30 s).

In order to reduce the annealing time and the cost, solvent annealing was carried out at higher temperatures (50° C., 60° C. and 70° C.) by varying annealing solvents. Annealing at 50° C. and 60° C. doesn't leads to phase separation (images are not shown here). In order to reduce the cost further, the solvening annealing was performed at room temperature, FIG. 10 shows the annealing time variation from 2 to 24 hours after exposure to THF:CHCl₃ with volume fraction of (2:1) at room temperature. Further tuning of the thickness led to reduction of annealing time to an hour at room temperature, exposed to (2:1) (THF:CHCl₃) in a confined and specified volume jar. The best result is achieved when a critical thickness is obtained, as illustrated in FIG. 10. The diameter of features at FIG. 10 was measured ˜115 nm using AFM topography images. The images are 2×2 micron.

Solvent annealing of block copolymer films on LED GaN substrate. FIG. 12 (a) polymer film phase separated on LED substrate, 12(b) after pattern transfer (GaN)). GaN was used as LED substrate and PS-b-P2VP BCP was spin coated and annealed with THF and chloroform (2:1) as annealing solvents at room temperature for 60 minutes. Phase separated BCP thin film were characterized using AFM and microdomains were ˜110 nm in diameter.

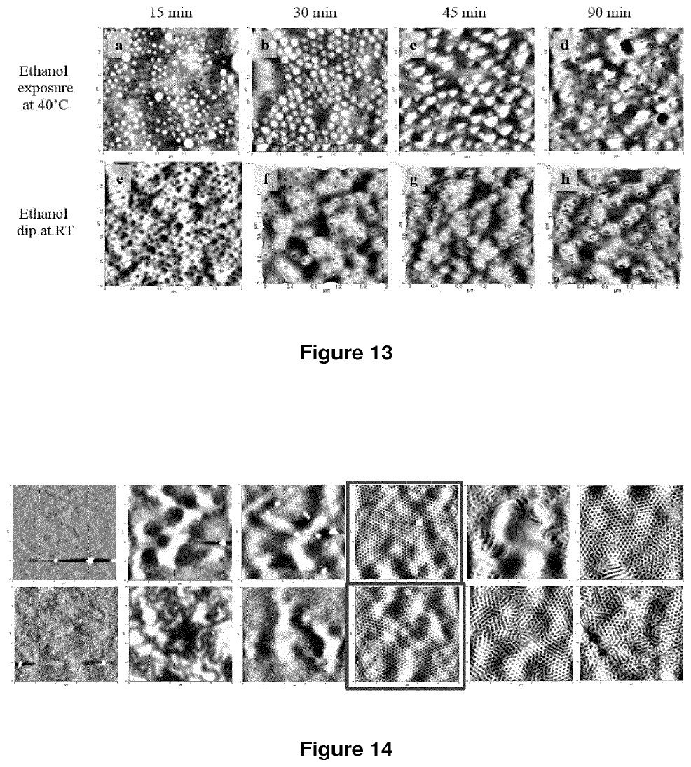

Metal oxide dots fabrication on Silicon and LED substrate can be achieved. The substrate was immersed in ethanol at 40° C. for 45 min to activate the P4VP domains. In the first attempt, the films were immersed in ethanol at room temperature from 15 minutes and up to 90 minutes (See FIGS. 13(e-h). FIG. 13 illustrates AFM topography image of the PS-b-P2VP films (a-d) after exposure to ethanol at 40° C. for 45 minutes and (e-h) after immersing the samples in ethanol at 40° C. for 45 minutes. The images are 2×2 microns. The film didn't survive the process. The structure was not retained and the films were delaminated from the substrate. To solve this problem, the films were exposed to ethanol vapour at 40° C. The result is shown in FIGS. 13 (a-d). After 30 minutes exposure a controlled pattern is reconstructed (FIG. 13b). To deposit the iron oxide in P4VP domains, 0.8% weight percent of iron (III) nitrate nonahydrate (Fe(NO₃)₃. 9H₂O) in ethanol solutions were spin-coated onto the activated film. UV/Ozone treatment was used to oxidize the precursor and remove the polymer. These iron oxide nanodot arrays were used as a hard mask for pattern transfer onto the substrate.

FIG. 14 illustrates the effect of critical film thickness and swelling ratio. The best ordered patterns are marked by frame or border. The films can be exposed to THF:ChCl₃ with different ratio, where the ratio can be from 1:1 to 10:1 or other way round depending on the application.

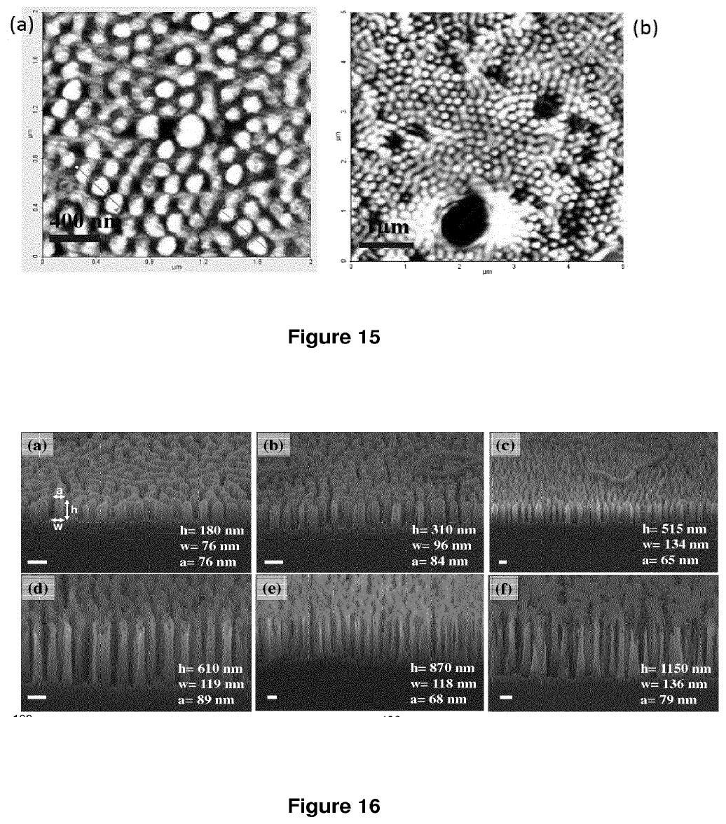

Iron nitrate solution was spin coated after ethanol treatment and exposed the film to UV/Ozone for 120 min to oxidize the precursor and to remove the polymer. FIG. 15 shows the AFM topography image of the iron oxide on silicon and GaN LED substrate. Fabricated iron oxide dots are ˜110 nm in diameter.

Sub-wavelength structures on substrate were fabricated by pattern transferring iron oxide dots to the substrate using a dry etcher.

The height of the structures can be precisely controlled by increasing the silicon etch time.

FIG. 16 illustrates cross section SEM images of (a) 180 nm high Si nanopillars after 5 minutes Si etch, (b) 310 nm high Si nanopillars after 10 minutes Si etch, (c) 515 nm Si nanopillars after 20 minutes etch, (d) 610 nm Si nanopillars after 30 minutes etch, (e) 870 nm Si nanopillars after 40 minutes etch, (f) 1150 nm Si nanopillars after 50 minutes etch. The diameter of the base is 76-136 nm. The apex diameter is varied 75-91 nm.

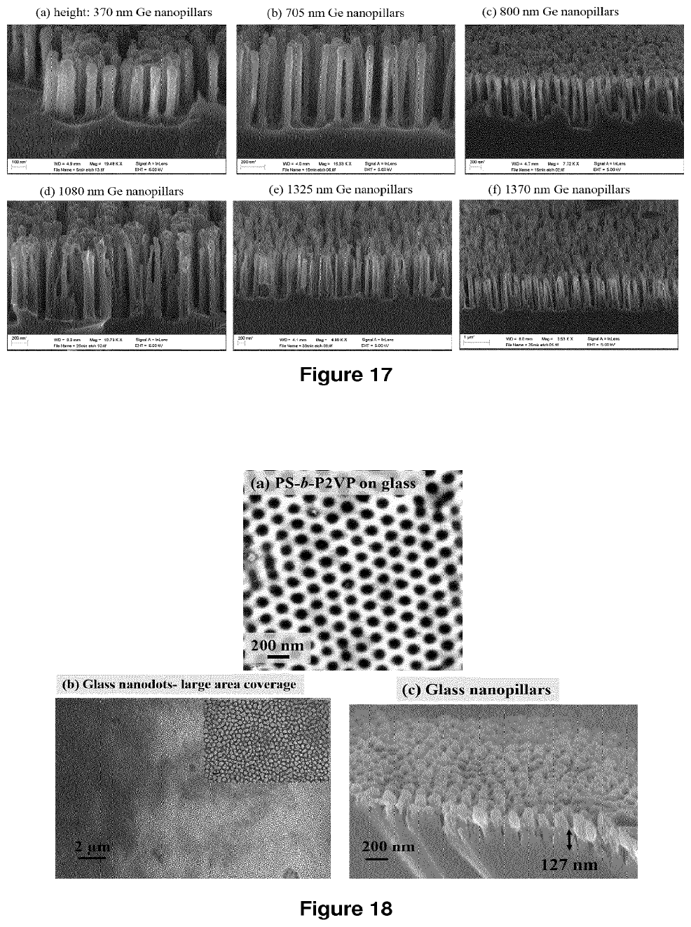

FIG. 17 illustrates SEM cross-section images of germanium nanopillars after 5-30 minutes etch with relevant height of the nanopillars at (a) 370 nm, (b) 705 nm, (c) 800 nm, (d) 1080 nm, 1325 nm and (f) 1370 nm.

FIG. 18 illustrates (A) AFM image of Ps-b-P2VP on glass, (b) Top-down SEM image of glass nanodots after pattern transfer of the metalised mask in (a), (b) SEM cross section image glass of nanopillars with metal oxide on top.

### Applications of the Invention

It will be appreciated that the method of the invention and nano-patterned surfaces have many applications in industry such as, but limited to, the following applications:
Boosting the performance of LEDs by minimising total internal reflection
Fabrication of black Silicon for photovoltaics, Near IR cameras and/or sensors,
Medical Devices, Healthcare imaging, brain probes and the like
Antireflective surfaces
Superhydrophobic surfaces
Structural colouring
Optical devices and applications, such as high-power laser windows, mobile phone screen covers, microlens arrays.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A method of fabricating a nano-patterned surface for application in a photonic, optical or other related device, said method comprising the steps of:
providing a substrate material;
depositing a block copolymer (BCP) material on the substrate material; and
phase separating the BCPs using at least one solvent selected to facilitate polymer chain mobilisation and lead to phase separation to fabricate said nano-patterned surface; wherein the nano-patterned surface comprises an ordered array of structures and having a domain or diameter of 100 nm or greater.

2. The method of claim 1 wherein the phase separation step uses two or more solvents and the solvent ratio is selected to facilitate the chain mobilisation and lead to phase separation.

3. The method of claim 1 wherein the structure domain or diameter size is tuned by selecting the volume fraction of the block components.

4. The method of claim 1 wherein the method takes place in a sealed housing defining a volume and the solvent is selected based on said volume.

5. The method of claim 1 wherein the step of depositing the block copolymer (BCP) material on the substrate material is performed by at least one of spin coating film; drop casting or dip coating.

6. The method of claim 1 comprising the step of texturing the height of the nano-patterned surface to a selected value.

7. The method of claim 1 wherein the nano-patterned surface comprises an array of pillar or wire like structures and having a domain or diameter of 80 nm or greater.

8. The method of claim 1 wherein the nano-patterned surface comprises an array of substantially conical shaped structures and having a diameter of approximately 80 nm or greater and a length of 80 nm or greater.

9. The method of claim 1 wherein the thickness of the BCP material is selected from a range of 100 nm to 500 nm.

10. The method of claim 1 wherein the substrate layer comprises at least one of: semiconductor material, silicon; gallium nitride; silicon carbide; glass; metal; plastic or sapphire.

11. The method of claim 1 comprising the step of controlling the size and shape of the nano-patterned surface.

12. The method of claim 1 comprising the step of incorporating metal oxide particles within the BCP material.

13. The method of claim 1 comprises the step of direct etching through a metallised mask.

14. The method of claim 1 comprising the step of transferring the nano-pattern to the substrate material to provide an antireflective surface with a low reflectivity in a wide range of wavelength.

15. The method of claim 1 wherein a subwavelength grating is made from the same material as the substrate and the index matching at the substrate interfaces provides improved anti-reflecting performance.

16. A photonic or optical device comprising a nano-patterned surface produced according to the method of claim 1.

17. A photonic or optical device comprising a substrate material wherein a surface of the substrate material comprises an array of pillar or wire like structures and having a domain or diameter of approximately 100 nm or greater, produced according to the method of claim 1.

18. The device as claimed in claim 17 wherein the substrate material and the array of pillar or wire like structures are the one material with no interface layer or boundary between the array and the substrate.
